(19) United States
(12) Patent Application Publication
(10) Pub. No.: US 2025/0204267 A1
(43) Pub. Date: Jun. 19, 2025

(54) MEMORY DEVICES WITH ENCAPSULATION LAYERS AND METAL VIA

(71) Applicant: International Business Machines Corporation, Armonk, NY (US)

(72) Inventors: Shravana Kumar Katakam, Lehi, UT (US); Ashim Dutta, Clifton Park, NY (US); Chih-Chao Yang, Glenmont, NY (US)

(21) Appl. No.: 18/538,891

(22) Filed: Dec. 13, 2023

(51) Int. Cl. H10N 50/80; H10B 61/00; H10N 50/01; H10N 50/20

(52) U.S. Cl. CPC H10N 50/80; H10B 61/00; H10N 50/01; H10N 50/20

(57) ABSTRACT

A semiconductor structure includes a memory device having a first electrode layer, at least one memory element layer disposed on the first electrode layer, and a second electrode layer disposed on the at least one memory element layer, a first encapsulation layer disposed on at least sidewalls of the first electrode layer and the at least one memory element layer, a second encapsulation layer disposed on the first encapsulation layer and above a top surface of the second electrode layer, and a metal via disposed on the top surface of the second electrode layer.

### BACKGROUND

Memory devices are used in a wide range of fields. For example, memory devices can be used in consumer, industrial, military, aeronautical and space applications. Memory devices may be composed of non-volatile memory or volatile memory. Many types of non-volatile memories are known in the art such as, for example, magnetoresistive random-access memory (MRAM), phase change memory (PCM), and resistive random-access memory (ReRAM), among others.

### SUMMARY

Illustrative embodiments of the present application include techniques for use in semiconductor manufacture. In an illustrative embodiment, a semiconductor structure, comprises a memory device comprising a first electrode layer, at least one memory element layer disposed on the first electrode layer, and a second electrode layer disposed on the at least one memory element layer, a first encapsulation layer disposed on at least sidewalls of the first electrode layer and the at least one memory element layer, a second encapsulation layer disposed on the first encapsulation layer and above a top surface of the second electrode layer, and a metal via disposed on the top surface of the second electrode layer.

In another illustrative embodiment, a semiconductor structure comprises a memory device comprising a first electrode layer, at least one memory element layer disposed on the first electrode layer, and a second electrode layer disposed on the at least one memory element layer, a first encapsulation layer disposed on at least sidewalls of the first electrode layer and the at least one memory element layer, a second encapsulation layer disposed on the first encapsulation layer and above a top surface of the second electrode layer, and a bit line contact disposed on the top surface of the second electrode layer and the second encapsulation layer. The bit line contact is separated from the first encapsulation layer by the second encapsulation layer.

In yet another illustrative embodiment, an integrated circuit comprises one or more semiconductor structures. At least one of the one or more semiconductor structures comprises a memory device comprising a first electrode layer, at least one memory element layer disposed on the first electrode layer, and a second electrode layer disposed on the at least one memory element layer, a first encapsulation layer disposed on at least sidewalls of the first electrode layer and the at least one memory element layer, a second encapsulation layer disposed on the first encapsulation layer and above a top surface of the second electrode layer, and a metal via disposed on the top surface of the second electrode layer.

### BRIEF DESCRIPTION OF THE DRAWINGS

FIG. 1 depicts a cross sectional view illustrating a semiconductor structure during an intermediate step of a method of fabricating a memory device, according to an illustrative embodiment.

FIG. 2 depicts a cross-sectional view illustrating the semiconductor structure following one or more additional etching processes, according to an illustrative embodiment.

FIG. 3 depicts a cross-sectional view illustrating the semiconductor structure following the formation of a first encapsulation layer, according to an illustrative embodiment.

FIG. 4 depicts a cross-sectional view illustrating the semiconductor structure following removal of portions of the first encapsulation layer, according to an illustrative embodiment.

FIG. 5 depicts a cross-sectional view illustrating the semiconductor structure following the formation of a second encapsulation layer, according to an illustrative embodiment.

FIG. 6 depicts a cross-sectional view illustrating the semiconductor structure following the formation of an interlevel dielectric layer (ILD), according to an illustrative embodiment.

FIG. 7 depicts a cross-sectional view illustrating the semiconductor structure following a dual damascene trench and via opening patterning process, according to an illustrative embodiment.

FIG. 8 depicts a cross-sectional view illustrating the semiconductor structure following the formation of a first contact and a first metal via in a logic area, a second contact and a second metal via in Region 1 of a memory area and a third contact in Region 2 of the memory area, according to an illustrative embodiment.

FIG. 9 is a cross-sectional view of a semiconductor structure starting from FIG. 3 following removal of portions of the first encapsulation layer, according to an illustrative alternative embodiment.

FIG. 10 is a cross-sectional view illustrating the semiconductor structure following the formation of the second encapsulation layer, according to an illustrative alternative embodiment.

FIG. 11 depicts a cross-sectional view illustrating the semiconductor structure following formation of an ILD layer over the second encapsulation layer, according to the illustrative alternative embodiment.

FIG. 12 depicts a cross-sectional view illustrating the semiconductor structure following a dual damascene trench and via opening patterning process, according to the illustrative alternative embodiment.

FIG. 13 depicts a cross-sectional view illustrating the semiconductor structure following the formation of the first contact and the first metal via in the logic area, the second contact and the second metal via in Region 1 of the memory area and the third contact in Region 2 of the memory area, according to the illustrative alternative embodiment.

### DETAILED DESCRIPTION

This disclosure relates generally to semiconductor devices, and more particularly to memory device structures having dual encapsulation layers and a metal via and methods for their fabrication. However, it is to be understood that embodiments of the invention are not limited to the illustrative methods, apparatus, systems and devices but instead are more broadly applicable to other suitable methods, apparatus, systems and devices.

Certain integration schemes require memory elements in the back-end-of-line (BEOL). Such memory elements may be formed in a column or pillar shape. The memory elements are included in memory devices such as, for example, phase-change random-access memory (PCRAM), resistive random-access memory (RRAM or ReRAM), and magnetic random-access memory (MRAM) devices.

In current memory devices, such as, for example, embedded MRAM devices, the current process has a lower opens and shorts margin due to variability between the array center to edge and from wafer center to edge. For example, it is difficult to make a clean electrical contact between a top metal contact and the top electrode formed on the magnetic tunnel junction (MTJ) element when the interlevel dielectric (ILD) layer is of a relatively high thickness, resulting in a higher opens and shorts margin. Accordingly, illustrative embodiments of the invention correspond to semiconductor structures having an embedded MRAM device which includes a top via contact that helps make contact to the MRAM bit at locations where the ILD layer thickness is higher buying opens margin. In addition, the semiconductor structure also includes a dual spacer where the top spacer acts as an etch stop layer to restrict the bottom spacer erosion avoiding hard shorts during any over etching process. Finally, the top spacer can serve as a stop layer during any ILD layer planarization process for better uniformity.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

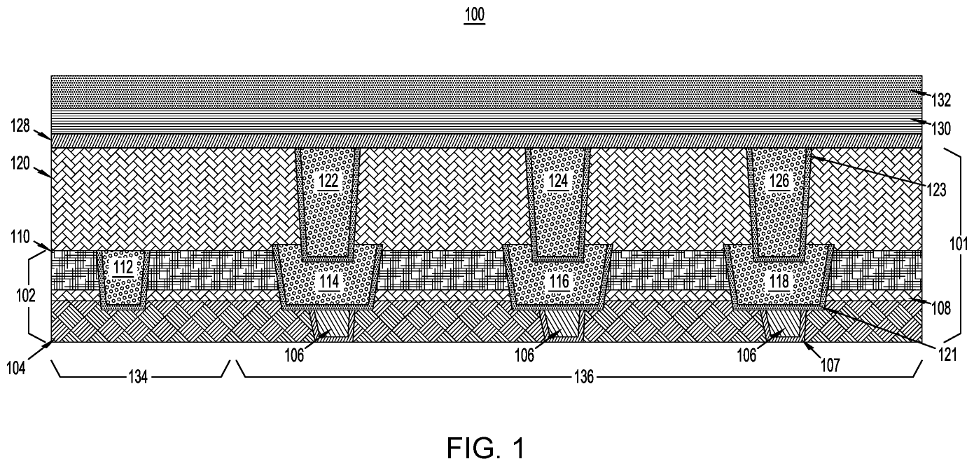

Illustrative embodiments for fabricating embedded memory devices will be described below with reference to FIGS. 1-13. By way of an example as well as for purposes of illustration, the semiconductor structure as presented in this disclosure includes a memory device of an MRAM device. The memory device includes a memory element having a magnetic tunnel junction (MTJ) element formed between a top and bottom electrode. In such a case, the MTJ stack layers may correspond to the device layer while the top and bottom electrodes may correspond to the top and bottom terminals which provide a conducting path for the device element.

It is understood that embodiments of the present disclosure are also applicable to other suitable types of memory elements such as PCM and ReRAM or other suitable types of memory elements. Such memory devices together with logic components are generally based on any suitable technology node. The memory device together with the logic components can be incorporated into standalone memory devices including, but not limited to, Universal Serial Bus (USB) or other types of portable storage units, or ICs, such as microcontrollers or system on chips (SoCs). In addition, the semiconductor structures and ICs and methods for forming same in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

FIGS. 1-8 illustrate a first non-limiting illustrative embodiment. For the purpose of clarity, several fabrication steps leading up to the production of semiconductor structure 100 as illustrated in FIG. 1 are omitted. In other words, semiconductor structure 100 does not necessarily start out in the form illustrated in FIG. 1, but may develop into the illustrated structure over one or more well-known processing steps which are not illustrated but are well-known to those of ordinary skill in the art.

Referring now to FIG. 1, a semiconductor structure 100 is shown during an intermediate step of a method of fabricating a memory device after memory device layers have been formed according to an embodiment of the invention. In this example, the semiconductor structure 100 comprises a metallization stack 101 that includes one or more layers. A first or bottom portion 102 of the metallization stack 101 may be disposed directly on a semiconductor stack. The bottom portion 102 of the metallization stack 101 may be comprised of one or more layers including a first layer 104, a second layer 108 and a third layer 110. The first layer 104 can comprise any oxide material such as, for example, low-k dielectric materials, ultra low-k (ULK) dielectric materials, tetraethyl orthosilicate (TEOS), etc. The second layer 108 may be disposed on and in contact with the first layer 104 and may comprise a capping material such as, for example, an NBLoK™ material, a nitride material (e.g., silicon nitride (SiN), silicon carbonitride (SiCN)) and the like. NBLoK™ material is from Applied Materials, Inc. of Santa Clara, CA, and is a nitrogen and hydrogen doped silicon carbide (SiCN(H)). The third layer 110 may be disposed on and in contract with the second layer 108 and comprise an insulating material such as an ILD layer including, for example, a low-k dielectric, ultra-low-k dielectric, and/or the like. It should be noted that the illustrative embodiments are not limited to the layers of the bottom portion 102 of the metallization stack 101 as shown in FIG. 1 and additional layers may be added and/or one or more layers may be removed.

The semiconductor structure 100 includes a plurality of patterned metal layers 106 each including a liner layer 107 formed in the first layer 104. Suitable material for the liner layer 107 includes, for example, niobium (Nb), niobium nitride (NbN), tungsten (W), tungsten nitride (WN), tantalum (Ta), tantalum nitride (TaN), titanium (Ti), titanium nitride (TiN), ruthenium (Ru), molybdenum (Mo), chromium (Cr), vanadium (V), palladium (Pd), platinum (Pt), rhodium (Rh), scandium (Sc), aluminum (Al) and other high melting point metals or conductive metal nitrides. The liner layer 107 is conformally formed on sidewalls and a bottom surface of a trench in the first layer 104. The plurality of patterned metal layers 106 are metallization contacts comprising, an electrically conductive metal deposited on the liner layer 107. Suitable electrically conductive metal includes, for example, tungsten, cobalt (Co), zirconium (Zr), tantalum (Ta), titanium (Ti), aluminum (Al), ruthenium (Ru), copper (Cu), metal carbides (e.g., tantalum carbide, titanium carbide, tantalum magnesium carbide), metal nitrides (e.g., titanium nitride), transition metal aluminides or combinations thereof.

Contacts, also referred to herein as wires or conductive lines, function as electrically conductive contacts or interconnects. The contacts form electrical connections between elements and/or devices, or to elements or devices. As used herein, a “contact” or “contact structure” includes an electrically conductive metal, and may further include a liner layer.

The bottom portion 102 of the metallization stack 101 may further include patterned metal layers 112, 114, 116 and 118 embedded therein. In the example shown in FIG. 1, the patterned metal layers 112 to 118 are embedded within the first layer 104, the second layer 108, and the third layer 110 of the bottom portion 102 of the metallization stack 101. The patterned metal layers 112 to 118, in one example, are metallization contacts comprising, an electrically conductive metal as discussed above. In addition, the patterned metal layers 112 to 118 each include a liner layer 121. Suitable material for the liner layer 121 can be any of those discussed above for the liner layer 107.

At least the patterned metal layer 112 is disposed within a logic area 134 of the semiconductor structure 100 while the patterned metal layer 106 and patterned metal layers 114 to 118 are disposed within a memory area 136 of the semiconductor structure 100. Although not shown, similar patterned metal layers may also extend from the contacts in the logic area.

A second or top portion 120 of the metallization stack 101 may be disposed on the bottom portion 102 of the metallization stack 101. In one example, the top portion 120 of the metallization stack 101 comprises one or more dielectric materials. Suitable dielectric materials include, for example, silicon carbonitride (SiCN:H), silicon carbide, silicon nitride, TEOS and the like. Accordingly, at least in some embodiments, the top portion 120 of the metallization stack 101 may also be referred to as “a first dielectric cap layer”. It should be noted that while the metallization stack 101 may include the top portion 120 disposed directly on the bottom portion 102, in various embodiments the metallization stack 101 may include one or more intervening metallization layers between the bottom portion 102 and the top portion 120. That is, the top portion 120 of the metallization stack 101 would be disposed on one or more intervening metallization layers, or other material layers, which would be disposed on the bottom portion 102 of the metallization stack 101.

In some examples, a dielectric insulating layer (not shown) may separate the second layer 108 from the first layer 104. This dielectric insulating layer may be used to separate at least some metal wiring, circuits, and junctions, in the second layer 108 from making direct electrical contact with metal wiring, circuits, and junctions, in the first layer 104. The dielectric insulating layer may be removed at selected locations to allow electrical interconnection, e.g., wiring and junctions, to extend from the second layer 108 down to the first layer 104, and/or further below to a semiconductor stack (not shown). The dielectric insulating layer may include, for example, dielectric material such as silicon oxide or carbon-doped oxide, or other low K dielectrics.

In illustrative embodiments, the top portion 120 of the metallization stack 101 comprises one or more electrode contacts 122, 124 and 126 (also referred to herein as “bottom electrode contacts 122 to 126”) within the memory area 136. In some embodiments, a top surface of the bottom electrode contacts 122 to 126 is planar with a top surface of the top portion 120 of the metallization stack 101 and a bottom surface of the electrode contacts 122 to 126 contacts a top surface of the patterned metal layers 114 to 118 within the memory area 136. The bottom electrode contacts 122 to 126 may comprise any conductive material as discussed above. In addition, the bottom electrode contacts 122 to 126 each include a liner layer 123. Suitable material for the liner layer 123 can be any of those discussed above for the liner layer 107. In one embodiment, the bottom electrode contacts 122 to 126 may be formed using a damascene process where metal is deposited inside the trench having sidewall liners such as, for example, titanium nitride (TiN), tantalum nitride (TaN), ruthenium (Ru), etc. In another embodiment, the bottom electrode contacts 122 to 126 may be formed using a subtractive etch process.

FIG. 1 further shows a plurality of memory device layers including a bottom electrode layer 128, memory element layers 130 (e.g., Magnetic tunnel junction (MTJ) stack layers) and a top electrode layer 132. The bottom electrode layer 128 is formed on and in contact with the bottom electrode contacts 122 to 126 and the patterned metal layers 114 to 118. In some embodiments, the bottom electrode layer 128 may comprise materials such as, for example, W, WN, Al, TaN, TiN, etc.

The top electrode layer 132 includes, for example, Nb, NbN, W, WN, Ta, TaN, Ti, TiN, Ru, Mo, Cr, V, Pd, Pt, Rh, Sc, Al and other high melting point metals or conductive metal nitrides. According to an embodiment, the thickness of the top electrode layer 132 is larger than that of the bottom electrode layer 128. For example, the thickness of the bottom electrode layer 128 can be in the range of about 50 angstroms to about 500 angstroms and the thickness of the top electrode layer 132 can be in the range of about 500 angstroms to about 1500 angstroms. The top electrode layer 132 is formed on the memory element layers 130, and the memory element layers 130 are formed on the bottom electrode layer 128. In the case of an MRAM, the memory element layers 130 include an MTJ structure comprising, for example, one or more magnetic fixed layers, non-magnetic barrier layers, free layers and oxide layers. The memory element layers 130 are not limited to those of an MRAM, and can include layers for memory elements of, for example, PCRAM, RRAM, ReRAM or other non-volatile memory devices.

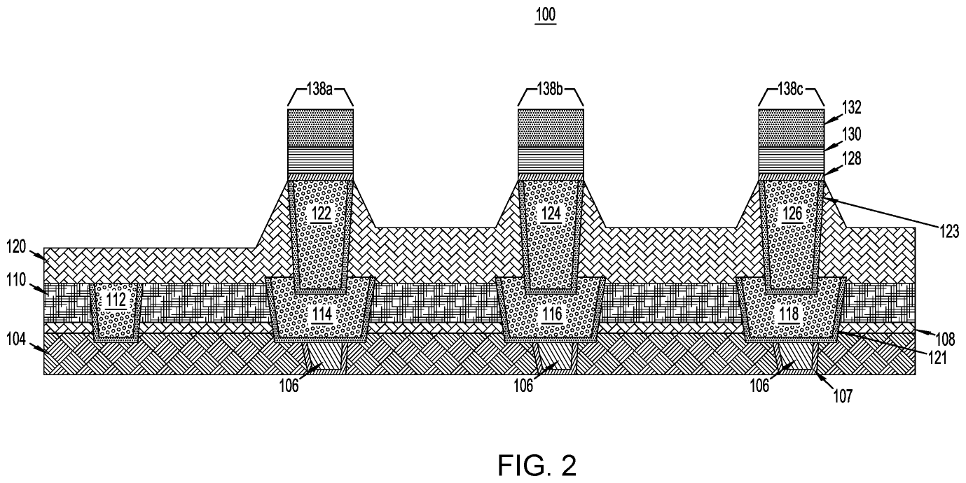

Referring now to FIG. 2, the semiconductor structure 100 is shown following one or more additional etching processes according to an embodiment of the invention. The one or more additional etching processes such as RIE or IBE are performed to pattern the top electrode layer 132, the memory element layers 130 and the bottom electrode layer 128. For example, a hardmask (not shown) can be deposited on the top electrode layer 132 and standard lithographic, patterning and etching techniques are carried out. This etching process forms a first magneto-resistive random access memory (MRAM) stack/pillar 138a, a second MRAM stack/pillar 138b and a third MRAM stack/pillar 138c each including the memory element layers 130 and the bottom electrode layer 128 under the top electrode layer 132. Although three MRAM stacks/pillars are shown, this is merely illustrative and any number of MRAM stacks/pillars are contemplated herein. In addition, the etching process allows for the top portion 120 to encapsulate the patterned metal layer 114 to 118.

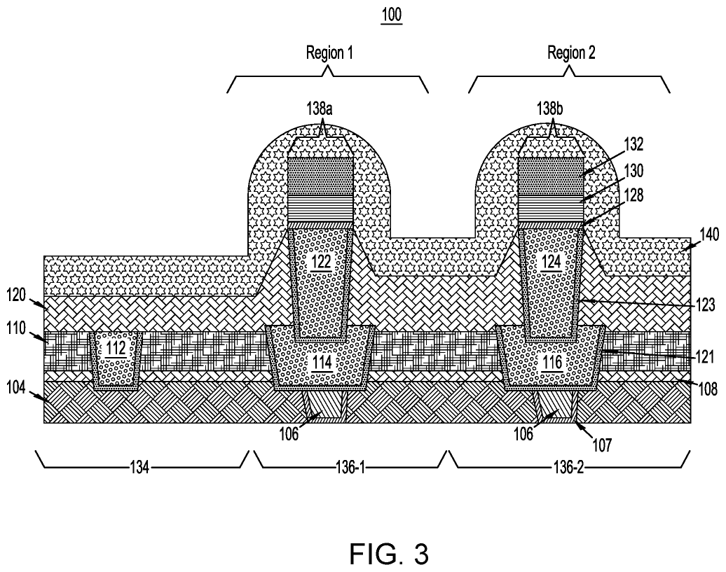

Referring to FIG. 3, the semiconductor structure 100 is shown following the formation of a first encapsulation layer 140 according to an embodiment of the invention. The first encapsulation layer 140 is deposited on the top portion 120 including an area disposed in the logic area 134, and also on exposed portions of the top electrode layer 132, the memory element layers 130 and the bottom electrode layer 128. The first encapsulation layer 140 is formed around the top electrode layer 132, the memory element layers 130 and the bottom electrode layer 128 to encapsulate the first MRAM stack/pillar 138a in Region 1, which is disposed in a first memory area 136-1, and the second MRAM stack/pillar 138b in Region 2, which is disposed in a second memory area 136-2. Suitable material for the first encapsulation layer 140 includes, for example, a nitride such as SiN or SiCN and the like. The first encapsulation layer 140 can be deposited using one or more conformal deposition techniques such as, for example, CVD or ALD.

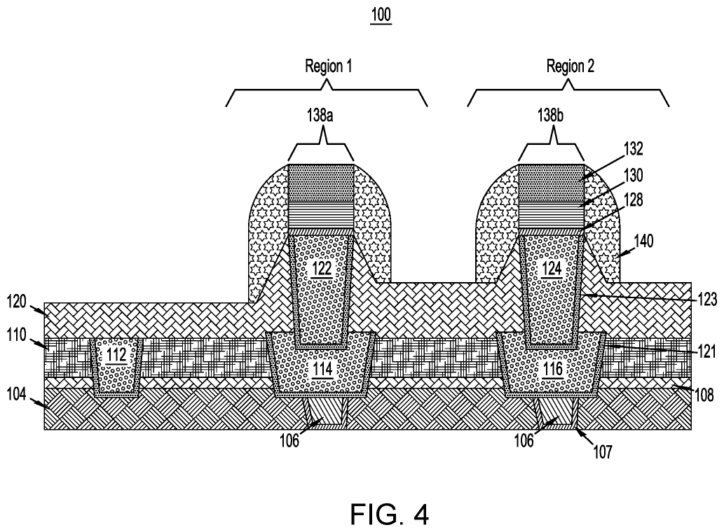

Referring to FIG. 4, the semiconductor structure 100 is shown after portions of the first encapsulation layer 140 are removed according to an embodiment of the invention. The portions of the first encapsulation layer 140 are removed in, for example, an etchback process, to expose at least a top surface and part of side surfaces of the top electrode layer 132. According to an embodiment, an upper part of the side surfaces of the top electrode layer 132 is exposed by the removal of the portions of the first encapsulation layer 140 in Region 1 and Region 2 and horizontal portions of the top portion 120. Following the etchback process, the first encapsulation layer 140 remains around other parts of the side surfaces of the top electrode layer 132, and around the memory element layers 130 and the bottom electrode layer 128, still encapsulating those portions of the first MRAM stack/pillar 138a and the second MRAM stack/pillar 138b.

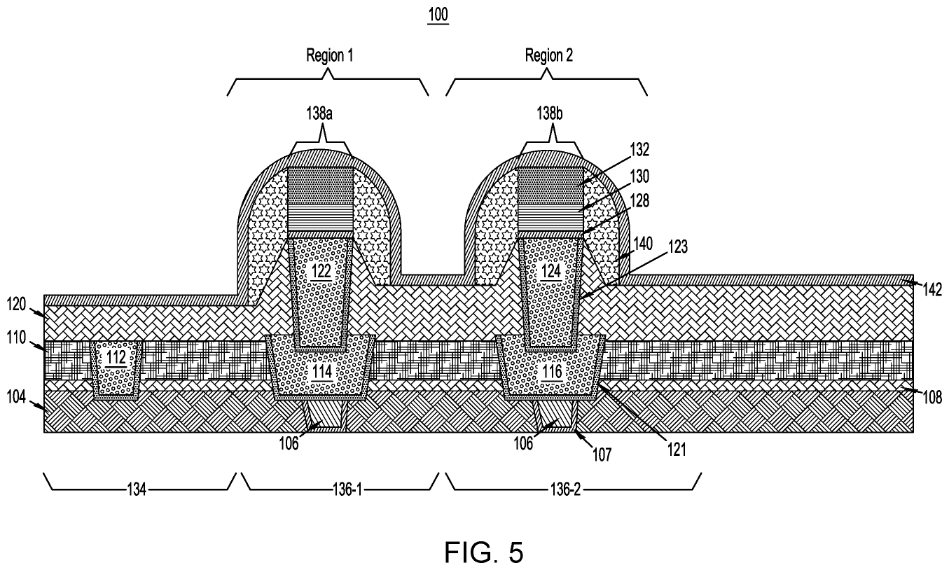

Referring to FIG. 5, the semiconductor structure 100 is shown following the formation of a second encapsulation layer 142 according to an embodiment of the invention. The second encapsulation layer 142 is deposited on the top portion 120 including the area disposed in the logic area 134, on the first encapsulation layer 140 and on exposed portions of the top electrode layer 132. The second encapsulation layer 142 is formed around the top electrode layer 132 such that together with the first encapsulation layer 140 these layers encapsulate the first MRAM stack/pillar 138a in Region 1, which is disposed in first memory area 136-1, and the second MRAM stack/pillar 138b in Region 2, which is disposed in second memory area 136-2. Suitable material for the second encapsulation layer 142 includes, for example, a nitride such as TaN or TiN and the like. The second encapsulation layer 142 can be deposited using one or more conformal deposition techniques such as, for example, CVD or ALD.

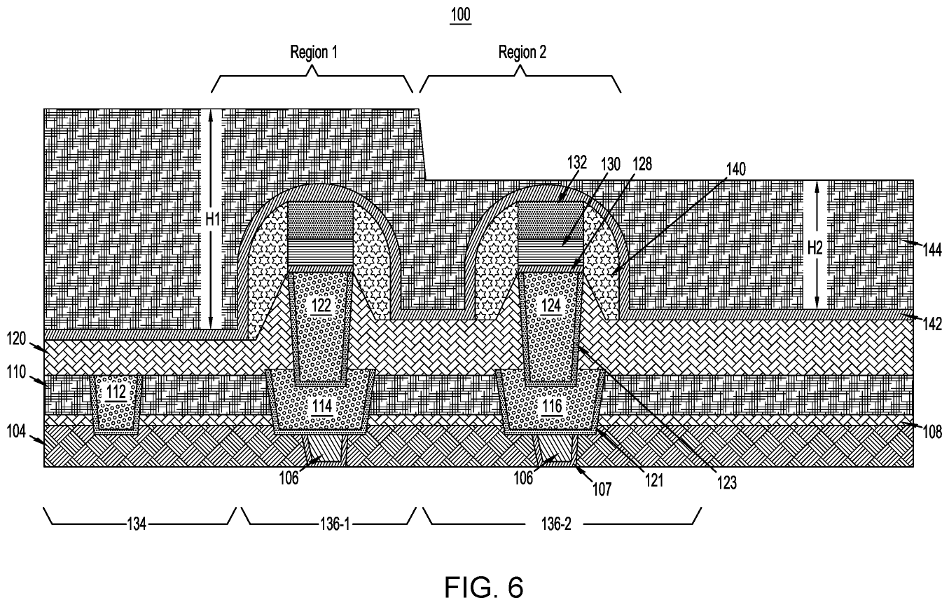

Referring to FIG. 6, the semiconductor structure 100 is shown following the formation of an ILD layer 144 according to an embodiment of the invention. The ILD layer 144 is formed over the second encapsulation layer 142. Suitable material for the ILD layer 144 includes, for example, SiOₓ, SiOC, ultra-low-k dielectrics or other suitable dielectric material. The ILD layer 144 can be deposited using one or more conformal deposition techniques such as, for example, CVD or ALD, followed by planarization such as CMP. In some embodiments, a height of the ILD layer 144 in the logic area 134 and in Region 1, which is disposed in first memory area 136-1 is of a first height, H1, and a height of the ILD layer 144 in Region 2, which is disposed in first memory area 136-1 is of a second height, H2, less than the first height H1. In some embodiments, the first height H1 can range from about 400 to about 1000 nanometers (nm). In some embodiments, the second height H2 can range from about 300 to about 900 nm. In some embodiments, the difference between the height of first height H1 and the height of second height H2 can range from about 10 nm to about 150 nm.

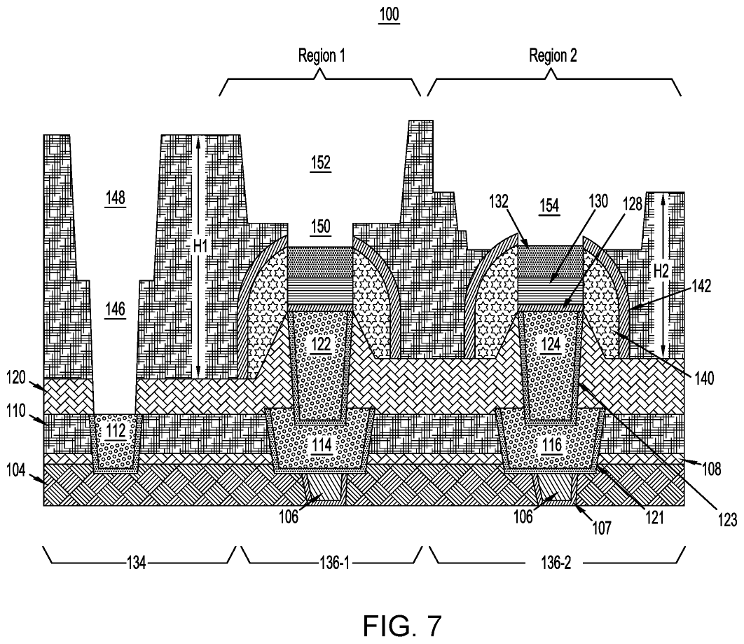

Referring to FIG. 7, the semiconductor structure 100 is shown following a dual damascene trench and via opening patterning process according to an embodiment of the invention. In embodiments, the dual damascene trench and via opening patterning process includes portions of the ILD layer 144 (e.g., portions not covered by a mask) being etched to form a first upper metallization level trench 148 and a via opening 146, and a second upper metallization level trench 152 and a via opening 150 in Region 1 of the first memory area 136-1. According to an embodiment, the etching is performed using, for example, a fluorocarbon based RIE. The first upper metallization level trench 148 and the via opening 146 are formed in the ILD layer 144 in the logic area 134. The via opening 146 under the first upper metallization level trench 148 is further formed through the top portion 120, until it reaches one of the contacts in the logic area 134, e.g., the patterned metal layer 112. The via opening 146 exposes a top surface of the patterned metal layer 112. The second upper metallization level trench 152 and the via opening 150 are formed in Region 1 of the first memory area 136-1 to expose a top surface of the top electrode layer 132.

FIG. 7 further shows a third upper metallization level trench 154 formed in Region 2 of the second memory area 136-2 to expose a top surface of the top electrode layer 132 and a portion of the second encapsulation layer 142. The third upper metallization level trench 154 is selectively etched with respect to the second encapsulation layer 142 so that the second encapsulation layer 142 remains above the top electrode layer 132 to physically separate the first encapsulation layer 140 from the metal contact formed in third upper metallization level trench 154 as discussed below.

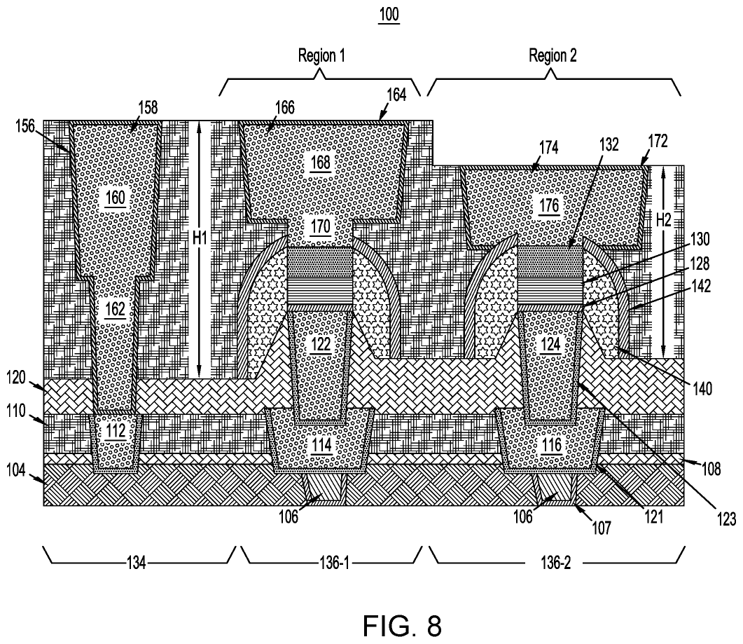

Referring to FIG. 8, the semiconductor structure 100 is shown following the formation of a first bit line contact 160 and a first metal via 162 in the logic area 134, a second bit line contact 168 and a second metal via 170 in Region 1 of the first memory area 136-1 and a third bit line contact 176 in Region 2 of the second memory area 136-2 according to an embodiment of the invention. In embodiments, the first upper metallization level trench 148 and the via opening 146 (see FIG. 7) are filled with a liner layer 156 on the sidewalls thereof and a metal fill layer 158 on the liner layer 156 to create the first bit line contact 160 and the first metal via 162 in logic area 134. In embodiments, the second upper metallization level trench 152 and the via opening 150 (see FIG. 7) are filled with a liner layer 164 on sidewalls thereof and a metal fill layer 166 on the liner layer 164 to create the second bit line contact 168 and the second metal via 170 in Region 1 of the first memory area 136-1. In embodiments, the third upper metallization level trench 154 is filled with a liner layer 172 on sidewalls thereof and a metal fill layer 174 on the liner layer 172 to create the third bit line contact 176 in Region 2 of the second memory area 136-2. Suitable material and deposition processes for the liner layers 156, 164 and 172 can be any of those discussed above for the liner layer 107. Suitable material and deposition processes for the metal fill layers 158 and 174 can be any of the electrically conductive metals discussed above. If necessary, a planarization process such as, for example, CMP can be carried out.

In some embodiments, the second bit line contact 168 is electrically linked to the top electrode layer 132 through the second metal via 170. In some embodiments, the second bit line contact 168 is physically separated from the second encapsulation layer 142 by the ILD layer 144. In some embodiments, the third bit line contact 176 is physically separated from the first encapsulation layer 140 by the second encapsulation layer 142.

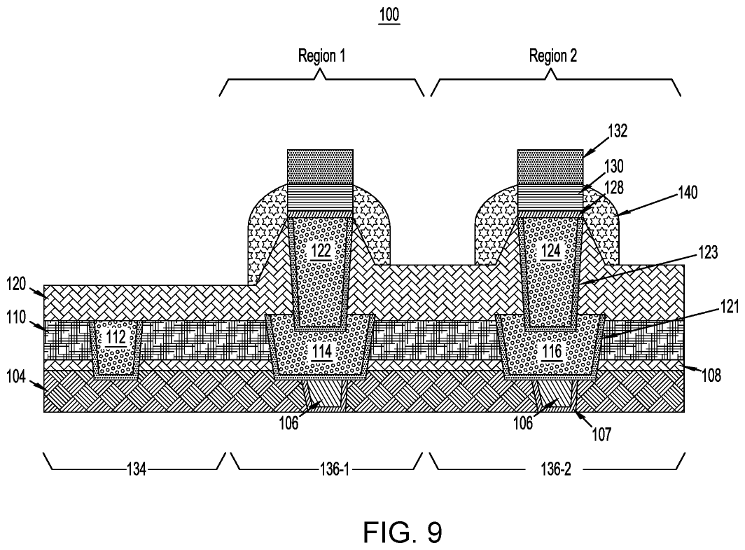

In accordance with a second illustrative embodiment depicted in FIGS. 9-13 starting from FIG. 3, FIG. 9 shows the semiconductor structure 100 following portions of the first encapsulation layer 140 being removed according to an embodiment of the invention. The portions of the first encapsulation layer 140 are removed by, for example, an etchback process, to expose at least a top surface and side surfaces of the top electrode layer 132. Following the etchback process, the first encapsulation layer 140 remains around and encapsulates the side surfaces of the memory element layers 130 and the bottom electrode layer 128.

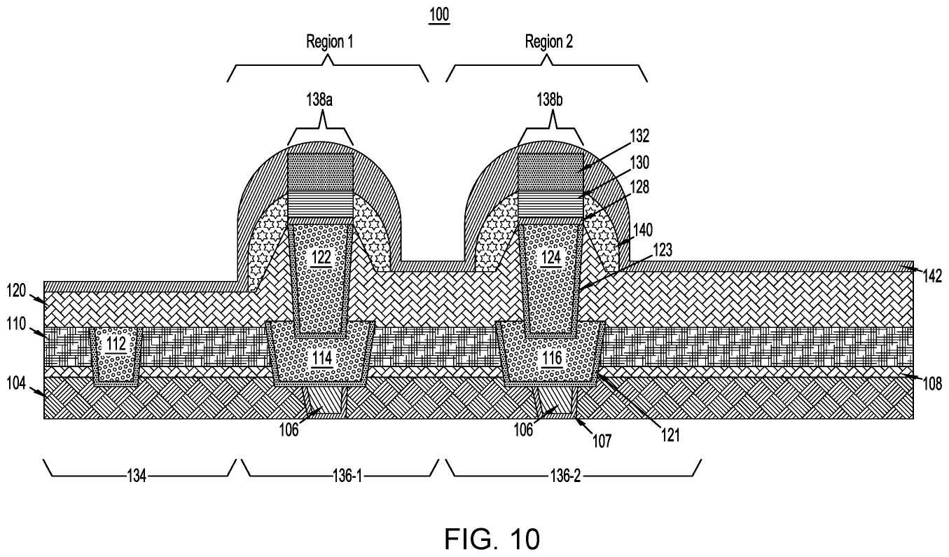

Referring to FIG. 10, the semiconductor structure 100 is shown following the formation of the second encapsulation layer 142 according to an embodiment of the invention. The second encapsulation layer 142 is deposited on the top portion 120 including the area disposed in the logic area 134, on the first encapsulation layer 140 and on the exterior surfaces of the top electrode layer 132. The second encapsulation layer 142 is formed around the top electrode layer 132 such that together with first encapsulation layer 140 these layers encapsulate the first MRAM stack/pillar 138a in Region 1, which is disposed in the first memory area 136-1, and the second MRAM stack/pillar 138b in Region 2, which is disposed in the second memory area 136-2. Suitable material and deposition techniques for the second encapsulation layer 142 includes those discussed above.

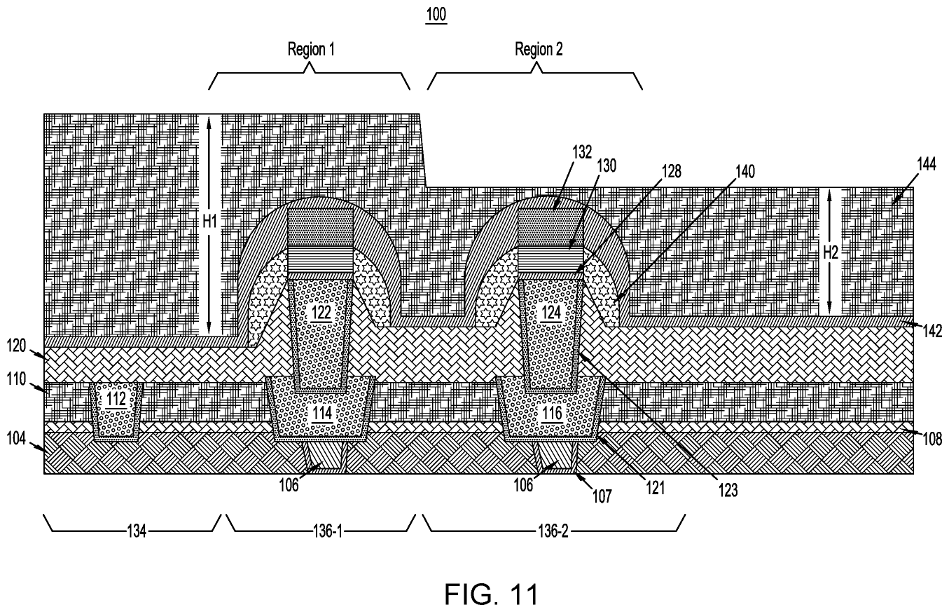

Referring to FIG. 11, the semiconductor structure 100 is shown following the formation of the ILD layer 144 over the second encapsulation layer 142, followed by planarization such as CMP according to an embodiment of the invention. In embodiments, a height of the ILD layer 144 in the logic area 134 and in Region 1, which is disposed in the first memory area 136-1, is of a first height, H1, and a height of the ILD layer 144 in Region 2, which is disposed in the second memory area 136-2, is of a second height, H2, less than the first height H1. As discussed above, in some embodiments, the first height H1 can range from about 400 to about 1000 nm, and the second height H2 can range from about 300 to about 900 nm. In some embodiments, the difference between the height of the first height H1 and the height of the second height H2 can range from about 10 nm to about 150 nm.

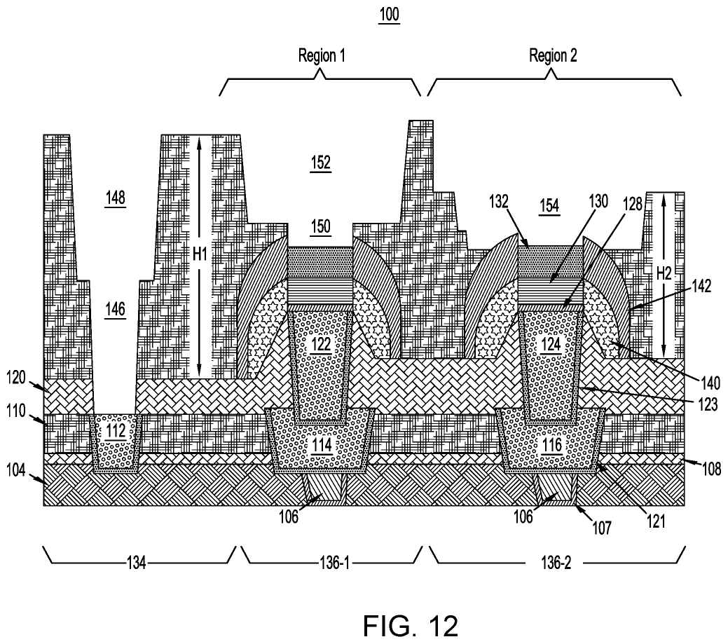

Referring to FIG. 12, the semiconductor structure 100 is shown following a dual damascene trench and via opening patterning process according to an embodiment of the invention. In embodiments, the dual damascene trench and via opening patterning process includes portions of the ILD layer 144 (e.g., portions not covered by a hard mask) being etched to form the first upper metallization level trench 148 and the via opening 146, and the second upper metallization level trench 152 and the via opening 150 in Region 1 of the first memory area 136-1. According to an embodiment, the etching is performed using, for example, a fluorocarbon based RIE. The first upper metallization level trench 148 and the via opening 146 are formed in the ILD layer 144 in the logic area 134. The via opening 146 under the first upper metallization level trench 148 is further formed through the top portion 120, until it reaches one of the contacts in the logic area 134, e.g., the patterned metal layer 112. The via opening 146 exposes a top surface of the patterned metal layer 112. The second upper metallization level trench 152 and the via opening 150 are formed in Region 1 of the first memory area 136-1 to expose a top surface of the top electrode layer 132.

FIG. 12 further shows the third upper metallization level trench 154 formed in Region 2 of the second memory area 136-2 to expose a top surface of the top electrode layer 132 and a portion of the second encapsulation layer 142. The third upper metallization level trench 154 is selectively etched with respect to the second encapsulation layer 142 so that a portion of the second encapsulation layer 142 remains above the top electrode layer 132 to physically separate the first encapsulation layer 140 from a metal contact formed in the third upper metallization level trench 154 as discussed below.

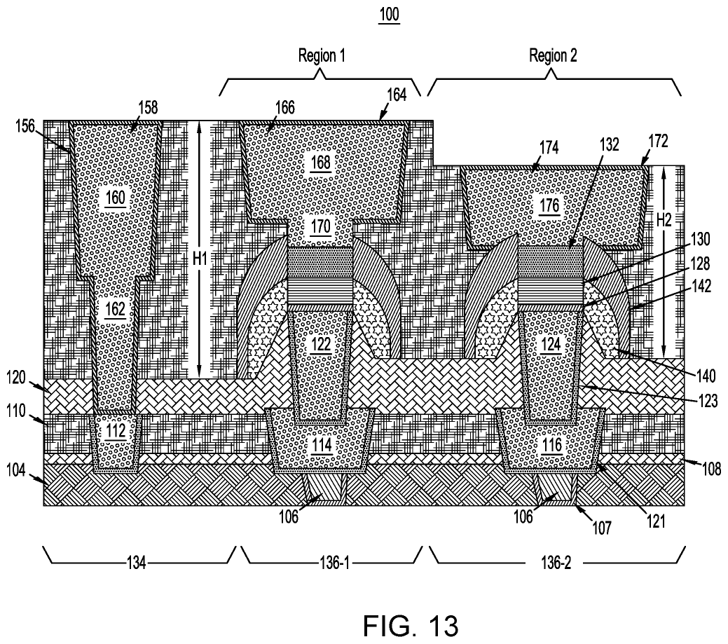

Referring to FIG. 13, the semiconductor structure 100 is shown following the formation of the first bit line contact 160 and the first metal via 162 in the logic area 134, the second bit line contact 168 and the second metal via 170 in Region 1 of the first memory area 136-1 and the third bit line contact 176 in Region 2 of the second memory area 136-2 according to an embodiment of the invention. The first bit line contact 160 and the first metal via 162 in the logic area 134, the second bit line contact 168 and the second metal via 170 in Region 1 of the first memory area 136-1 and the third bit line contact 176 in Region 2 of the second memory area 136-2 can be formed as discussed above.

It is to be appreciated that the various materials, processing methods (e.g., etch types, deposition types, etc.) and dimensions provided in the discussion above are presented by way of example only. Various other suitable materials, processing methods, and dimensions may be used as desired.

Semiconductor devices and methods for forming same in accordance with the above-described techniques can be employed in various applications, hardware, and/or electronic systems. Suitable hardware and systems for implementing embodiments of the invention may include, but are not limited to, sensors and sensing devices, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a memory device comprising a first electrode layer, at least one memory element layer disposed on the first electrode layer, and a second electrode layer disposed on the at least one memory element layer;
a first encapsulation layer disposed on at least sidewalls of the first electrode layer and the at least one memory element layer;
a second encapsulation layer disposed on the first encapsulation layer and above a top surface of the second electrode layer; and
a metal via disposed on the top surface of the second electrode layer.

2. The semiconductor structure according to claim 1, wherein the second encapsulation layer is further disposed on sidewalls of the second electrode layer.

3. The semiconductor structure according to claim 1, wherein the first encapsulation layer is further disposed on sidewalls of the second electrode layer.

4. The semiconductor structure according to claim 1, wherein a bottom surface of the first electrode layer is disposed on an electrode contact.

5. The semiconductor structure according to claim 4, wherein the electrode contact is disposed on a patterned metal layer.

6. The semiconductor structure according to claim 1, wherein the metal via connects a bit line contact to the second electrode layer.

7. The semiconductor structure according to claim 6, further comprising an interlevel dielectric layer disposed on the second encapsulation layer, the metal via and the bit line contact.

8. The semiconductor structure according to claim 7, wherein the bit line contact is separated from the second encapsulation layer by the interlevel dielectric layer.

9. The semiconductor structure according to claim 6, wherein the metal via and the bit line contact are part of a dual damascene structure.

10. A semiconductor structure, comprising:
a memory device comprising a first electrode layer, at least one memory element layer disposed on the first electrode layer, and a second electrode layer disposed on the at least one memory element layer;
a first encapsulation layer disposed on at least sidewalls of the first electrode layer and the at least one memory element layer;
a second encapsulation layer disposed on the first encapsulation layer and above a top surface of the second electrode layer; and
a bit line contact disposed on the top surface of the second electrode layer and the second encapsulation layer;
wherein the bit line contact is separated from the first encapsulation layer by the second encapsulation layer.

11. The semiconductor structure according to claim 10, wherein the second encapsulation layer is further disposed on sidewalls of the second electrode layer.

12. The semiconductor structure according to claim 10, wherein the first encapsulation layer is further disposed on sidewalls of the second electrode layer.

13. The semiconductor structure according to claim 10, wherein a bottom surface of the first electrode layer is disposed on an electrode contact.

14. The semiconductor structure according to claim 13, wherein the electrode contact is disposed on a patterned metal layer.

15. The semiconductor structure according to claim 10, further comprising an interlevel dielectric layer disposed on the second encapsulation layer and the bit line contact.

16. An integrated circuit, comprising:
one or more semiconductor structures, wherein at least one of the one or more semiconductor structures comprises:
a memory device comprising a first electrode layer, at least one memory element layer disposed on the first electrode layer, and a second electrode layer disposed on the at least one memory element layer;
a first encapsulation layer disposed on at least sidewalls of the first electrode layer and the at least one memory element layer;
a second encapsulation layer disposed on the first encapsulation layer and above a top surface of the second electrode layer; and
a metal via disposed on the top surface of the second electrode layer.

17. The integrated circuit according to claim 16, wherein the metal via connects a bit line contact to the second electrode layer.

18. The integrated circuit according to claim 17, further comprising an interlevel dielectric layer disposed on the second encapsulation layer, the metal via and the bit line contact.

19. The integrated circuit according to claim 18, wherein the bit line contact is separated from the second encapsulation layer by the interlevel dielectric layer.

20. The integrated circuit according to claim 17, wherein the metal via and the bit line contact are part of a dual damascene structure.
